(19) United States
(12) Patent Application Publication
(10) Pub. No.: US 2024/0091812 A1
(43) Pub. Date: Mar. 21, 2024

(54) DEVICE AND METHOD FOR MANUFACTURING A DEVICE

(71) Applicant: TDK Electronics AG, Munich (DE)

(72) Inventors: Wolfgang Wallnöfer, Deustschlandsberg (AT); Aditya Rajapurkar, Graz (AT); Gert Turel, Bärnbach (AT); Zdravko Mijocevic, Deustschlandsberg (AT); Andreas Pentscher-Stani, Leibnitz (AT)

(21) Appl. No.: 18/263,971

(22) PCT Filed: Feb. 1, 2022
(86) PCT No.: PCT/EP2022/052338

§ 371 Date: Aug. 2, 2023

(30) Foreign Application Priority Data
Feb. 15, 2021 (DE) 10 2021 103 477.9

(51) Int. Cl. B06B 1/06; H10N 30/03; H10N 30/045; H10N 30/063; H10N 30/87

(52) U.S. Cl. CPC B06B 1/0622; H10N 30/03; H10N 30/045; H10N 30/063; H10N 30/875; G06F 3/016

(57) ABSTRACT

A device and a method are disclosed. In an embodiment, a device includes an oscillating body on which a piezoelectric element is fixed by a solder joint.

### CROSS-REFERENCE TO RELATED APPLICATIONS

This patent application is a national phase filing under section 371 of PCT/EP2022/052338, filed Feb. 1, 2022, which claims the priority of German patent application 102021103477.9, filed Feb. 15, 2021, each of which is incorporated herein by reference in its entirety.

### TECHNICAL FIELD

The present invention relates to a device for oscillation excitation and a method of manufacturing such a device. In particular, the device is suitable for generating a haptic signal.

### BACKGROUND

Devices in which piezoelectric elements are attached to an oscillating body to generate a haptically perceptible signal are known, for example, from US 2014/0327839 A1 and WO 2000/141264 A1. In these devices, an electrical excitation of one or more piezoelectric elements can generate a mechanical resonant oscillation of the oscillating body. In order to be able to deflect a touch-sensitive screen sufficiently strongly with such a device, large oscillating bodies populated with numerous piezoelectric elements are required, which limit the possible applications of this technology in terms of space requirements, energy consumption and costs.

US 2014/0327839 A1 and WO 2000/141264 A1 describe that the piezoelectric elements are attached to the oscillating body by an organic adhesive compound, for example based on epoxy or acrylic resin, the organic adhesive compound sometimes having additives to increase electrical conductivity.

### SUMMARY

Embodiments provide an improved device. For example, the improved device should provide reduced power consumption, or a reduced number of piezoelectric elements, or a reduced drive voltage.

A device is proposed which has an oscillating body on which a piezoelectric element is fixed by a solder joint.

Compared to a glued joint, the solder joint has a higher rigidity. Oscillations generated by the piezoelectric element can, therefore, be transmitted better to the oscillating body by the solder joint. At the same time, the solder joint damps the oscillation hardly at all or even not at all. Adhesive joints exhibit viscoelastic behavior, which dampens an oscillation generated by the piezoelectric element. Since the solder joint does not exhibit viscoelastic behavior, this does not lead to damping of the oscillation in the case of the solder joint.

In addition, the solder joint enables an improved, more reliable electrical contact between the piezoelectric element and the oscillating body compared to an adhesive joint. If an organic adhesive with additives to increase electrical conductivity is used for the adhesive joint, this represents a compromise in adhesive strength, since the additives have no adhesive effect and their addition thus reduces the adhesive effect of the adhesive. Alternatively, very thin adhesive layers can be used, which allow electrical contacting even without such additives, but which also exhibit a poorer adhesive effect due to the low thicknesses.

Due to the better mechanical connection of the piezoelectric element to the oscillating body when using a solder joint, the oscillating body can be excited to oscillate with more than twice the amplitude for the same excitation signal of the piezoelectric element compared to an adhesive joint. In this way, the solder joint makes it possible to generate a stronger haptic signal at the oscillating body for the same excitation signal. This can make it possible to design oscillating bodies that have a smaller number of piezoelectric elements or to drive the piezoelectric elements with a weaker excitation signal. If the number of piezoelectric elements is reduced, the footprint of the device can be reduced and new applications of the technique are opened up. By using a weaker excitation signal, the energy consumption of the device can be reduced.

The piezoelectric element may have a monolithic piezoelectric layer. The piezoelectric layer may be disposed between two electrodes disposed on the outer surfaces of the piezoelectric element. The piezoelectric element may comprise a piezoelectric ceramic, such as lead zirconate titanate (PZT) ceramic. Alternatively, the piezoelectric element may comprise a piezoelectric polymer.

Alternatively, the piezoelectric element may be a multilayer element comprising stacked piezoelectric layers and inner electrodes. The piezoelectric layers may comprise a piezoelectric ceramic, for example a PZT ceramic, or a piezoelectric polymer.

The piezoelectric element can be a piezoelectric actuator. The piezoelectric actuator can be designed to generate oscillations with a frequency in the ultrasonic range. Oscillations with a frequency between 40 kHz and 120 kHz may be excited. In particular, frequencies with between 60 and 80 kHz can be excited.

In a further mode of operation, the piezoelectric element may be used as a sensor. In this case, the piezoelectric element can be configured to detect a pressure applied to an input element connected to the oscillating body.

A single piezoelectric element or several piezoelectric elements can be attached to the oscillating body by one solder joint each. The solder joints can be manufactured simultaneously in a single soldering process. The oscillating body can have a length between 50 mm and 300 mm.

The oscillating body may comprise a conductive material or be made of a conductive material. For example, the oscillating body may comprise aluminum or stainless steel. Stainless steel has the advantage that it has high solderability and can be well connected with a solder joint. Aluminum has the advantages of comparatively low weight and high strength.

If the oscillating body has a conductive material, the oscillating body can be connected to an electrode of the piezoelectric element via the solder joint. An electrical potential, for example a ground potential, can be applied to the electrode via the oscillating body.

Alternatively, the oscillating body may comprise or be made of a non-conductive material. For example, the oscillating body may have a glass or a ceramic or a glass-reinforced plastic or may be made of one of these materials. Additionally, lines may be applied to a side of the oscillating body facing the piezoelectric element. The lines can be applied, for example, in a coating process.

The oscillating body may be coated with a coating, and the solder joint may be disposed on the coating. The coating can serve, for example, to improve the wettability of the oscillating body with a solder material. The coating may be sputtered on. The coating may comprise a layer comprising chromium, a layer comprising nickel, and a layer comprising silver. Such a coating makes it possible to significantly improve the wettability of an oscillating body made of aluminum.

The piezoelectric element may have a Curie temperature that is higher than a melting temperature of a material of the solder joint. For example, the Curie temperature of the piezoelectric element may be greater than 300° C. This may prevent depolarization of the piezoelectric element during the soldering process in which the material of the solder joint is heated to a temperature greater than a melting temperature. For example, the soldering process can be carried out at a temperature between 260° C. and 280° C., for example at 270° C. Alternatively, it is also possible to perform polarization of the piezoelectric element only after the soldering process in which the piezoelectric element is attached to the oscillating body has been completed.

The oscillating body may have a T-shaped cross-section comprising a first region having a first width and a second region having a second width, the second width being greater than the first width and the first region being centered on the second region, wherein the piezoelectric element is arranged on a side of the second region facing away from the first region. Such a shaped oscillating body may allow oscillations generated by the piezoelectric element to be transmitted to an input element, such as a touch-sensitive screen, while amplifying the amplitude of the oscillation. The piezoelectric element may be configured to excite the oscillating body to oscillate at a frequency in the ultrasonic range.

The solder joint may have a lead-free solder, such as a SnAgCu solder.

The piezoelectric element may have a first electrode and a second electrode. At least two leads may be disposed on the oscillating body. The first electrode may be connected to one of the at least two lines by the solder joint. The second electrode may be connected to another of the at least two lines by a second solder joint. An excitation signal may thereby be applied to the electrodes via the lines. For example, an AC voltage may be applied between the electrodes via the lines.

The first electrode may be arranged on the side of the piezoelectric element facing the oscillating body. The second electrode can be arranged on the side of the piezoelectric element facing away from the oscillating body and extend over a side wall of the piezoelectric element to the side of the piezoelectric element facing the oscillating body. Both electrodes can be contacted to the lines via one solder joint each, whereby the two solder joints can have the same solder material and can be manufactured in a single solder process, for example a single reflow solder process.

In an alternative embodiment, the piezoelectric element may also comprise a first electrode and a second electrode, wherein the first electrode is arranged on a side of the piezoelectric element facing the oscillating body and wherein the second electrode is arranged on a side of the piezoelectric element facing away from the oscillating body. In this embodiment, the first electrode may be connected to the oscillating body through the solder joint and the second electrode may be connected to a connection element through a second solder joint. The connection element may be a line connected to, for example, a flexible printed circuit. The solder joint and the second solder joint may have the same solder material and may be manufactured in a single solder process, such as a single reflow solder process.

Another aspect of the present invention relates to an apparatus comprising the device described above and an input element. The input element has a top surface and a bottom surface, wherein the oscillating body is attached to the bottom surface of the input element. In particular, the oscillating body may be attached to the bottom surface of the input element with a side facing away from the piezoelectric element, for example via the first region. The input element may be a screen, preferably a touch-sensitive screen.

The oscillating body may be connected to the input element in such a manner that an oscillation having a frequency in the ultrasonic range is excited at the input element when the piezoelectric element excites the oscillating body to oscillate, wherein a standing wave may be generated at the top surface of the input element. By using the solder joint between the piezoelectric element and the oscillating body, it can be made possible that the oscillation generated by the piezoelectric element is damped as little as possible by the connection of the piezoelectric element to the oscillating body, and thus a strong signal can be transmitted to the input element. In particular, this makes it possible to generate a signal that is more haptically perceptible than a signal generated with a comparative device in which the piezoelectric element is connected to the oscillating body by an adhesive joint.

The standing wave can lead to a modulation of a friction on the top surface. This modulation can represent a haptically perceptible signal.

According to another aspect, the present invention relates to a method of manufacturing a device comprising an oscillating body and a piezoelectric element, wherein the piezoelectric element is connected to the oscillating body by a solder joint. The device may be the device described above.

The solder joint can be created in a reflow soldering process or a vapor phase soldering process or by a thermal mode soldering process.

The piezoelectric element can be polarized before or after the piezoelectric element is connected to the oscillating body using the solder joint.

Two electrical connections used to apply an excitation voltage to the piezoelectric element can be formed in a single soldering process. The electrical connections may be the solder joint and a second solder joint. The solder joint and the second solder joint may be formed simultaneously using the same solder process and the same solder material.

The oscillating body may have at least two lines, wherein a first electrode of the piezoelectric element is contacted to one of the at least two lines by the solder joint, wherein a second electrode of the piezoelectric element is contacted to another of the at least two lines by a second solder joint, and wherein the solder joint and the second solder joint are formed in a single solder process.

### BRIEF DESCRIPTION OF THE DRAWINGS

In the following, preferred embodiments of the invention are described in more detail with reference to the figures.

FIG. 1 shows a device comprising an oscillating body and a piezoelectric element attached thereto;

FIG. 2 shows a microscope image of a section of the device shown in FIG. 1;

FIG. 3 shows an apparatus comprising the device shown in FIG. 1;

FIG. 4 shows a first embodiment example of the device in perspective view;

FIG. 5 shows the result of a comparison measurement;

FIG. 6 shows a device according to a second embodiment example; and

FIG. 7 shows a third embodiment example of the device.

### DETAILED DESCRIPTION OF ILLUSTRATIVE EMBODIMENTS

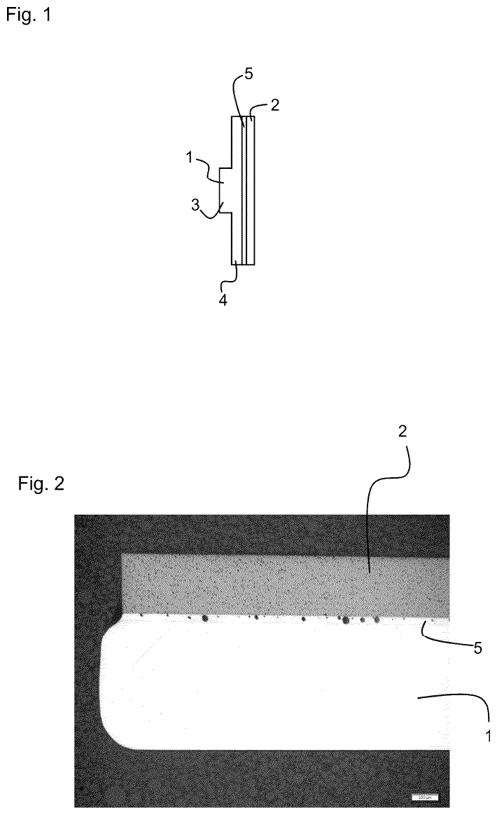

FIG. 1 shows a device comprising an oscillating body 1 and a piezoelectric element 2 attached thereto. The piezoelectric element 2 is a piezoelectric actuator designed to cause the oscillating body 1 to oscillate. A plurality of piezoelectric elements 2 may be attached to the oscillating body 1.

The oscillating body 1 has a T-shaped cross-section. The oscillating body has a first region 3 which forms a vertical line of the T-shape in the cross-section of the oscillating body 1. Further, the oscillating body 1 has a second region 4 which forms a horizontal line of the T-shape in cross-section. The piezoelectric element 2 is attached to a side of the second region 4 that faces away from the first region 3.

The piezoelectric element 2 is attached to the oscillating body 1 by a solder joint 5. The solder joint 5 has a lead-free solder material. The solder material may be SnAgCu solder, for example. In addition to the mechanical attachment of the piezoelectric element 2 to the oscillating body 1, the solder joint 5 also ensures electrical contact between the piezoelectric element 2 and the oscillating body 1.

The piezoelectric element 2 can be excited to oscillate at a frequency in the ultrasonic range. For this purpose, an AC voltage can be applied to the piezoelectric element 2 as an excitation signal. The excitation signal can be applied to the piezoelectric element 2 via the oscillating body 1.

The piezoelectric element 2 and the oscillating body 1 are connected to each other in such a way that the oscillation of the piezoelectric element 2 is transmitted to the oscillating body 1 and excites the oscillating body 1 to oscillate at a frequency in the ultrasonic range. The solder joint 5 has a high rigidity and does not damp the oscillation during transmission from the piezoelectric element 2 to the oscillating body 1, or damps it only insignificantly.

The piezoelectric element 2 has metallic electrodes. A first electrode 9 covers the surface of the piezoelectric element 2 facing the oscillating body 1. A second electrode 10 covers the surface of the piezoelectric element 2 facing away from the oscillating body 1. The first electrode 9 is attached to the oscillating body 1 via the solder joint 5.

The electrodes 9, 10 can be generated by thin film technology or by thick film technology. For example, the piezoelectric element 2 can be metallized with a silver paste in a thick-film process to generate the electrodes 9, 10.

The oscillating body 1 may comprise a conductive material or may consist of a conductive material. For example, the oscillating body 1 may comprise aluminum or stainless steel, or may consist of aluminum or stainless steel. Aluminum exhibits insufficient solderability. Therefore, an oscillating body 1 comprising aluminum may additionally comprise a coating that improves solderability. The coating can be sputtered on, for example. The coating may consist of several partial layers. The coating may have a layer comprising chromium, a layer comprising nickel and a layer comprising silver.

FIG. 2 shows a microscope image of a section of the device shown in FIG. 1.

FIG. 2 shows the piezoelectric element 2, the solder joint 5 and the oscillating body 1.

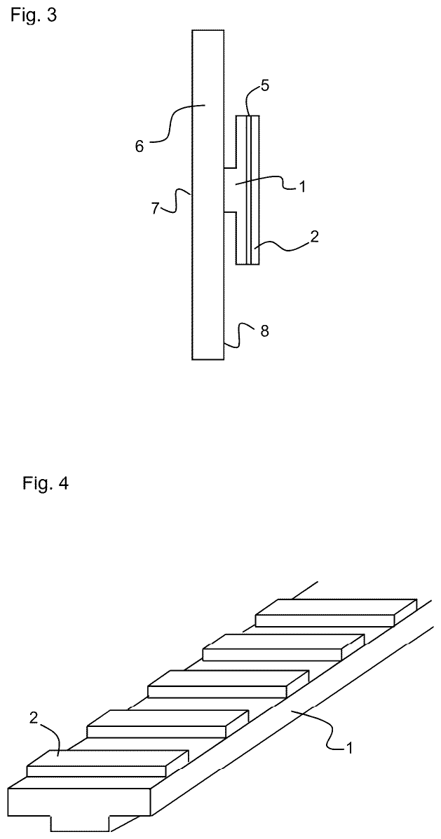

FIG. 3 shows a device which comprises the device shown in FIG. 1. The device additionally comprises an input element 6. The input element 6 is a touch-sensitive screen. The input element 6 has a top surface 7, which can be touched by a user, for example with his finger or a stylus, and a bottom surface 8, which is opposite the top surface 7 and to which the oscillating body 1 is attached. The first region 3 of the oscillating body 1 is attached to the bottom surface 8 of the input element 6.

The oscillating body 1 is configured to transmit the oscillation to the input element 6 when the oscillating body 1 is excited by the piezoelectric element 2 to oscillate at a frequency in the ultrasonic range. The oscillation transmitted to the input element 6 generates a surface standing wave on the top surface 7 of the input element 6. A user who touches the top surface 7 of the input element 6 feels a modulation of the friction generated by the standing wave. This modulation of the friction represents a haptically perceptible signal for the user. In particular, the standing wave can generate a deformation of the top surface 7 of the input element 6 with an amplitude in the micrometer range, by which overpressure areas are generated on the top surface 7. The overpressure regions lead to a reduction of the friction coefficient, which can be haptically perceived by the user.

FIG. 4 shows a part of a first embodiment example of the device in perspective view.

According to the first embodiment example, the oscillating body 1 has a base body with a T-shaped cross-section, which consists of aluminum. The oscillating body 1 further has a Cr/Ni/Ag coating which has been applied to the base body by means of sputtering.

The oscillating body according to the first embodiment example comprises a length between 150 mm and 200 mm. The length of the oscillating body is defined as its extension in a direction perpendicular to the cross-section shown in FIG. 1.

Attached to the oscillating body 1 in the first embodiment example are sixteen piezoelectric elements 2 comprising a PZT ceramic, with FIG. 4 showing only a section of the device. In other embodiments, the oscillating body 1 comprises a different number of piezoelectric elements 2.

In the first embodiment example, the piezoelectric elements 2 were each connected to the oscillating body 1 by a solder joint 5 comprising a SnAgCu solder formed by reflow soldering.

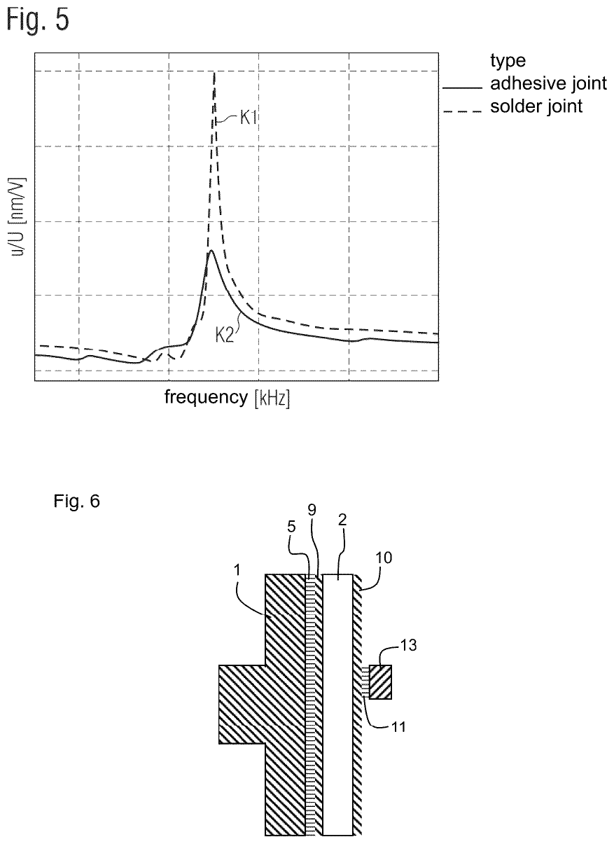

FIG. 5 shows the result of a comparison measurement in which the device according to the first embodiment example was compared with a reference object.

An identical oscillating body was used as a reference object, to which sixteen identical piezoelectric elements were attached by an adhesive joint with acrylic resin.

An AC voltage was applied to the piezoelectric elements 2 of the first embodiment example and to the piezoelectric elements of the reference object in each case. In both cases, this excited an oscillation of the respective oscillating body 1. A laser Doppler vibrometer was used to measure an amplitude of the oscillation of the oscillating body 1. In the measurement, a frequency of the voltage applied to the piezoelectric elements 2 was changed, and the maximum amplitude of oscillation at the oscillating body 1 for the respective frequency was measured in each case. The results of this measurement are plotted in FIG. 5, where the frequency is plotted in arbitrary units on the horizontal axis and the displacement of the oscillating body 1 is plotted on the vertical axis.

Curve K1 shows the measured values determined for the first embodiment example. Curve K2 shows the measured values determined for the reference object. The maximum of curve K1 determined for the first embodiment example is more than twice as high as the maximum of curve K2 determined for the reference object. The comparative measurement shows that by using a solder joint 5 to attach the piezoelectric elements 2 to the oscillating body 1 compared to an adhesive joint of the piezoelectric elements 2 to the oscillating body 1, an amplitude of the oscillation of the oscillating body 1 is increased with an identical excitation signal. An improvement of the amplitude by a factor of 2.4 was measured.

This improvement in the oscillation amplitude when a solder joint 5 is used results from the fact that the solder joint 5 has a higher rigidity than the adhesive joint and that the solder joint 5, unlike the adhesive joint, does not exhibit viscoelastic behavior. Both properties result in the solder joint 5 damping the oscillation generated by the piezoelectric element 2 less than an adhesive joint. Another advantage of the solder joint 5 over an adhesive joint is that the solder joint 5 enables better electrical contact between the piezoelectric element 2 and the oscillating body 1 than an adhesive joint.

Compared to a glued joint, the solder joint 5 leads to an oscillation behavior of the oscillating body 1 with a higher oscillation quality. Therefore, the peak of curve K1 is higher than the peak of curve K2 and therefore the peak of curve K1 has steeper slopes.

FIG. 6 shows a device according to a second embodiment example.

According to the second embodiment example, the oscillating bodies 1 have a length between 50 mm and 150 mm, for example 90 mm. According to the second embodiment example, the oscillating bodies 1 comprise stainless steel. An additional coating of the oscillating body 1 can be dispensed with, since stainless steel has good solderability.

According to the second embodiment example, eight piezoelectric elements 2 comprising a PZT ceramic are attached to the oscillating body 1 by means of a solder joint 5. In particular, the first electrode of the piezoelectric elements 2 is connected to the oscillating body 1 by the solder joint 5. Via the oscillating body 1, the first electrodes 9 are connected to a voltage source or a ground.

The second electrode 10, which is arranged on the side of the piezoelectric element 1 facing away from the oscillating body 1, is connected to a connection element 13 via a second solder joint 11. The connection element 13 is configured to apply an electrical potential to the second electrode 10. The connection element 13 may be a connection line connected to a flexible printed circuit.

The solder joint 5 and the second solder joint 11 can be manufactured together in a single process step. The solder joint 5 and the second solder joint 11 can be formed using the same process. The solder joint 5 and the second solder joint 11 each have a lead-free solder, for example a SnAgCu solder, and were manufactured by means of a reflow process.

The second embodiment example was compared with a further reference object. The oscillating body of the further reference object is identical to the oscillating body 1 of the second embodiment example. Eight piezoelectric elements were attached to the oscillating body of the further reference object, which are identical in construction to the piezoelectric elements 2 of the second embodiment example. For the further reference object, the piezoelectric elements were bonded to the oscillating body using epoxy resin. Comparison of the second embodiment example with the further reference object also shows that by attaching the piezoelectric elements 2 to the oscillating body 1, an amplitude of oscillation of the oscillating body 1 is increased compared with a reference object in which the piezoelectric elements are bonded to the oscillating body.

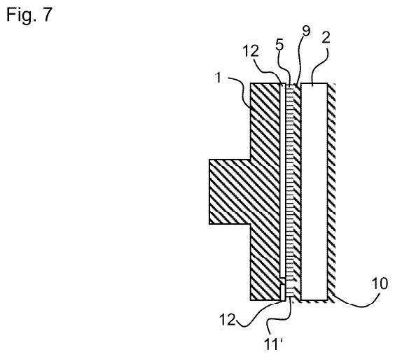

FIG. 7 shows a third embodiment example of the device.

According to the third embodiment example, the oscillating body 1 has a non-conductive material. The oscillating body 1 may comprise a glass, a ceramic or a glass-reinforced plastic or may be made of one of these materials.

Two or more electrical lines 12 are applied to the oscillating body 1 by coating methods. The first electrode 9 and the second electrode 10 of the piezoelectric element 2 are designed to be soldered simultaneously with the lines 12 on the oscillating body 1. The first electrode 9 faces the oscillating body 1 and is contacted to one of the lines on the oscillating body 1 by the solder joint 5. The second electrode 10 extends from the side of the piezoelectric element 2 facing away from the oscillating body 1, over a side wall of the piezoelectric element 2, to the side of the piezoelectric element 2 facing the oscillating body 1. At the side of the piezoelectric element 2 facing the oscillating body 1, the second electrode 10 is contacted with another of the lines 12 on the oscillating body 1. In this case, the second electrode 10 is contacted with the oscillating body 1 by a second solder joint 11′.

The solder joint 5 between the first electrode 9 and one of the lines 12 and the second solder joint 11′ between the second electrode 10 and another of the lines 12 are formed simultaneously in a single soldering process.

1-17. (canceled)

18. A device comprising:
an oscillating body on which a piezoelectric element is fixed by a solder joint.

19. The device according to claim 18,
wherein the oscillating body comprises a conductive material, or
wherein the oscillating body comprises a non-conductive material.

20. The device according to claim 18, wherein the oscillating body is coated with a coating and the solder joint is arranged on the coating.

21. The device according to claim 18, wherein the piezoelectric element has a Curie temperature higher than a melting temperature of a material of the solder joint.

22. The device according to claim 18,
wherein the oscillating body has a T-shaped cross-section comprising a first region having a first width and a second region having a second width,
wherein the second width is greater than the first width,
wherein the first region is centered on the second region, and
wherein the piezoelectric element is arranged on a side of the second region facing away from the first region.

23. The device according to claim 18, wherein the piezoelectric element is configured to excite the oscillating body to oscillate at a frequency in an ultrasonic range.

24. The device according to claim 18, wherein the solder joint comprises a lead-free solder.

25. The device according to claim 18,
wherein the piezoelectric element comprises a first electrode and a second electrode,
wherein at least two lines are arranged on the oscillating body,
wherein the first electrode is connected to one of the at least two lines by the solder joint, and
wherein the second electrode is connected to the other of the at least two lines by a second solder joint.

26. The device according to claim 18,
wherein the piezoelectric element comprises a first electrode and a second electrode,
wherein the first electrode is arranged on a side of the piezoelectric element facing the oscillating body,
wherein the second electrode is arranged on a side of the piezoelectric element facing away from the oscillating body,
wherein the first electrode is connected to the oscillating body by the solder joint, and
wherein the second electrode is connected to a connection element via a second solder joint.

27. An apparatus comprising:
the device according to claim 18; and
an input element,
wherein the input element has a top surface and a bottom surface, and
wherein the oscillating body is attached to the bottom surface of the input element.

28. The apparatus according to claim 27, wherein the input element is a touch-sensitive screen.

29. The apparatus according to claim 27,
wherein the oscillating body is connected to the input element in such a way that a oscillation with a frequency in an ultrasonic range is excited at the input element when the piezoelectric element excites the oscillating body to an oscillation, and
wherein a standing wave is generated at the top surface of the input element.

30. A method for manufacturing a device comprising an oscillating body and a piezoelectric element, the method comprising:
connecting the piezoelectric element to the oscillating body by a first solder joint.

31. The method according to claim 30, further comprising:
producing the first solder joint in a reflow soldering process or a vapor phase soldering process or by a thermal mode soldering.

32. The method according to claim 30, further comprising:
polarizing the piezoelectric element before the piezoelectric element is connected to the oscillating body by the solder joint, or
polarizing the piezoelectric element after the piezoelectric element is connected to the oscillating body by the solder joint.

33. The method according to claim 30, further comprising:
forming the first solder joint and a second solder joint in a single soldering process,
wherein the solder joint and the second solder joint are configured to apply an excitation voltage to the piezoelectric element.

34. The method according to claim 30,
wherein the oscillating body has at least two lines,
wherein a first electrode of the piezoelectric element is contacted with one of the at least two lines through the solder joint,
wherein a second electrode of the piezoelectric element is contacted with another one of the at least two lines by a second solder joint, and
wherein the first solder joint and the second solder joint are formed in a single soldering process.
